(19) United States
(12) Patent Application Publication
(10) Pub. No.: US 2009/0004863 A1
(43) Pub. Date: Jan. 1, 2009

(54) POLISHING LIQUID AND POLISHING METHOD USING THE SAME

(75) Inventor: Tetsuya KAMIMURA, Haibara-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 12/146,031

(22) Filed: Jun. 25, 2008

(30) Foreign Application Priority Data
Jun. 26, 2007 (JP) 2007-167901

(51) Int. Cl. H01L 21/306; C09K 13/00

(52) U.S. Cl. 438/692; 252/79.1; 257/E21.23

(57) ABSTRACT

The present invention provides a polishing liquid for polishing a ruthenium-containing barrier layer, the polishing liquid being used in chemical mechanical polishing for a semi-conductor device having a ruthenium-containing barrier layer and conductive metal wiring lines on a surface thereof, the polishing liquid comprising an oxidizing agent; and a polishing particulate having hardness of 5 or higher on the Mohs scale and having a composition in which a main component is other than silicon dioxide (SiO₂). The present invention also provides a polishing method for chemical mechanical polishing of a semi-conductor device, the method contacting the polishing liquid with the surface of a substrate to be polished, and polishing the surface to be polished such that contacting pressure from a polishing pad to the surface to be polished is from 0.69 kPa to 20.68 kPa.

### CROSS-REFERENCE TO RELATED APPLICATION

This application claims priority under 3 5 USC 119 from Japanese Patent Application No. 2007-167901, the disclosure of which is incorporated by reference herein.

### BACKGROUND OF THE INVENTION

1. Field of the Invention

The present invention relates to a polishing liquid employed in the manufacture of a semi-conductor device. More particularly, it relates to a polishing liquid which is preferably employed to polish a barrier layer of a substrate using mainly ruthenium as a barrier metal, for planarizing during a process for forming wiring lines on a semi-conductor device.

2. Description of the Related Art

In recent years, in the development of semi-conductor devices such as semi-conductor integrated circuits (hereinafter, referred to as “LSI”), increased density and integration have been sought by reducing the thickness of wiring lines and creating multiple layers thereof in order to miniaturize and increase the speeds of such devices. Moreover, various types of technologies, such as chemical mechanical polishing (hereinafter, referred to as “CMP”), and the like, have been employed in order to achieve this objective. CMP is an essential technology for surface planarization of processed layers, such as interlayer insulation films, for plug formation, for formation of embedded metal wiring lines, and the like, and CMP performs smoothing of a substrate and eliminates excessive metallic thin films from wiring line formation, and eliminates excessive barrier layer on the surface of insulating films.

A conventional method of CMP is one in which a polishing pad is fixed to the surface of a circular polishing table (polishing platen), the surface of the polishing pad is impregnated with a polishing liquid, the surface of the substrate (wafer) is pressed onto the pad, and both the polishing platen and the wafer are rotated while a predetermined amount of pressure (polishing pressure) is applied from the backsides thereof, such that the surface of the wafer is thereby planarized via the mechanical abrasion produced therefrom.

When semi-conductor devices such as LSIs are produced, fine lines are formed in multiple wiring layers, and a barrier metal such as of Ta, TaN, Ti or TiN is pre-formed in order to prevent diffusion of the wiring material into interlayer insulation film(s), and in order to improve adhesion of the wiring line material, when forming the metal wiring lines, such as of copper, in each of these layers.

In order to form each wiring layer, in general, a CMP process on metallic film (hereinafter, referred to as “metallic film CMP) is first performed at a single stage or at multiple stages to remove excess wiring material that has been deposited by plating or the like, and thereafter, a CMP process is carried out to remove barrier metal material (barrier metal) that has been exposed on the surface of the metallic film (hereinafter, referred to as “barrier metal CMP”). However, metallic film CMP can cause over-polishing, referred to as dishing, and occurrence of erosion of the wiring lines portions.

In order to reduce such dishing, in such barrier metal CMP, which follows the metallic film CMP, a wiring layer should be formed in which level differences due to dishing, erosion, and the like are ultimately reduced by regulating the polishing rate of the metal wiring portion and the polishing rate of the barrier metal portion. Specifically, in barrier metal CMP, it is preferable that the polishing rates of the barrier metal and insulation layer are moderately high, since dishing due to over-polishing of the wiring portion and erosion resulting from dishing may occur when the polishing rates of the barrier metal and the interlayer insulation film are relatively low when compared with to the polishing rate of the metal wiring material. Not only does this have the advantage of improving the barrier metal CMP throughput, but there is a requirement to relatively increase the polishing rates of the barrier metal and the insulation layer for the above reasons, since dishing is often caused by metallic film CMP in practice.

In recent years, with reduction of the thickness of wiring lines, a smaller thickness that does not reduce the barrier effect is also required in the barrier layer that protects metal wiring. As a result, ruthenium has been under scrutiny since it has a superior barrier effect even when formed as a thin layer. Since ruthenium has a higher hardness as compared with tantalum, which is generally used in the barrier layer, ruthenium is thought to exhibit more remarkable effects with respect to problems specific to barrier layer polishing than when tantalum is used.

A metal polishing liquid employed in CMP generally includes abrasive grains (for example, aluminum oxide or silica) and an oxidizing agent (for example, hydrogen peroxide or persulfuric acid). The basic polishing mechanism is thought to be that the metal surface is oxidized with the oxidizing agent, and then the oxide film formed thereby is removed with the abrasive grains.

However, when a polishing liquid including these sorts of solid abrasive grains is used in a CMP process, problems such as polishing damage (scratching), a phenomenon in which the entire polishing surface is over-polished (thinning), a phenomenon in which the polished metallic surface is dished (dishing), and a phenomenon in which plural metallic wiring surfaces are dished due to over-polishing of the insulator placed between the metallic wiring layers (erosion), and the like, may occur.

Moreover, there are cost-related problems, such as a conventionally employed cleaning process for eliminating residual polishing liquid from a semi-conductor surface after polishing with a polishing liquid containing solid abrasive grains can be complicated, and such as the requirement that solid abrasive grains must be precipitated when disposing of liquid after such cleaning (waste liquid).

The following investigations have been conducted with regard to a polishing liquid containing this type of solid abrasive grains.

For example, a CMP polishing agent and a polishing method that aim to achieve a high polishing rate, with virtually no occurrence of scratching is proposed (for example, Japanese Patent Application Laid-Open No. 2003-17446), a polishing composition and a polishing method for improving washability in CMP is proposed (for example, Japanese Patent Application Laid-Open No. 2003-142435), and a polishing composition that aims to prevent agglomeration of abrasive grains is proposed (for example, Japanese Patent Application Laid-Open No. 2000-84832).

However, even in the polishing liquids, there is still no technology for achieving a high polishing rate when polishing a barrier layer, while inhibiting scratching caused by the agglomeration of solid abrasive grains.

Further, in recent years, with reduction of the thickness of wiring lines, improvement in the step coverage of a barrier metal in addition to that of a copper seed film has been required, and new film forming processes have been under development. Among these, in particular, a film formed by deposition using an atomic layer deposition (ALD) system has superior performance over that of a film formed by a sputtering system (sputtering method) or a physical vapor deposition (PVD) system, which have conventionally been used to cover a barrier metal, in view of copper diffusion performance, reduction in RC time constant, and reliability, and is also excellent in terms of cost and extensibility. Film deposition using an ALD system is a method using a chemical reaction on a substrate surface, which forms a film by alternately supplying plural kinds of gases, or gaseous raw materials to a reaction chamber, and is characterized in that film thickness can be controlled at an atomic layer level and a film of better quality can be formed at a lower temperature. Specifically, the resulting film can minimize the volume of the barrier layer of a via hole or a trench and reduce wiring resistance, whereby the RC time constant of a device is reduced.

Conventionally, while an ALD system has been employed to cover the barrier metal, a barrier film formed by a sputtering system has been used to assess a liquid for polishing a metal. As described above, since the film quality of a barrier metal film that is to be polished differs depending on the film deposition system, polishing behavior can be entirely different in many cases. According to the assessment of the present inventors, it was found that even when the same polishing liquid is used, a ruthenium film formed by the sputtering system exhibits a polishing rate that is several-fold to several ten-fold higher as compared with a ruthenium film formed by ALD system. Since it is unclear whether conventional metal liquids can also achieve a superior polishing rate in films formed by deposition using not only the sputtering system but also the ALD system, a metal polishing liquid which can exhibit a polishing performance without any practical problems even on a barrier film formed by the ALD system and, in particular, on a ruthenium film, is desired.

### SUMMARY OF THE INVENTION

The present invention provides a polishing liquid using solid abrasive grains that is employed in a barrier CMP polishing process of a barrier layer containing ruthenium. The present invention provides a polishing liquid for a metal which can achieve a superior polishing rate when polishing a ruthenium-containing barrier layer. Further, the present invention also provides a chemical mechanical polishing method using the polishing liquid for a metal, which can achieve a high polishing rate of a barrier layer when a ruthenium is used for the barrier layer.

The present invention has been made in view of the above circumstances and provides a polishing liquid.

Namely, a first aspect of the present invention is a polishing liquid for polishing a ruthenium-containing barrier layer, the polishing liquid being used in chemical mechanical polishing for a semi-conductor device having the ruthenium-containing barrier layer and conductive metal wiring lines on a surface thereof, and the polishing liquid comprising: an oxidizing agent; and a polishing particulate having hardness of 5 or higher on the Mohs scale and having a composition in which a main component is other than silicon dioxide (SiO₂).

A second aspect of the present invention is a polishing method for chemical mechanical polishing of a semi-conductor device, the method comprising: contacting a polishing liquid comprising an oxidizing agent and a polishing particulate having hardness of 5 or higher on the Mohs scale and a composition in which a main component is other than silicon dioxide (SiO₂), with a surface of a substrate to be polished, the substrate having a ruthenium-containing barrier layer and conductive metal wiring lines on a surface thereof; and polishing the surface to be polished such that contact pressure from a polishing pad to the surface to be polished is from 0.69 kPa to 20.68 kPa.

### DETAILED DESCRIPTION OF THE INVENTION

Hereafter, the specific embodiments of the present invention will be explained.

The polishing liquid of the present invention is a polishing liquid for polishing a barrier layer of a semi-conductor device provided with metal wiring and a ruthenium-containing barrier layer. The polishing liquid contains at least, as essential components: an oxidizing agent, and a polishing particulate which has a hardness of 5 or higher on the Mohs scale and has a composition containing a main component other than silicon dioxide (SiO₂) (hereinafter, occasionally referred to as a “specific polishing particulate”); and arbitrarily includes a known component such as a corrosion suppressing agent, a compound having a carboxyl group, a surfactant or a water-soluble polymer. Here, the “main component” refers a component, the amount of which contained in the polishing particulate is 50% by mass or more with respect to the total amount of the polishing particulate.

The “polishing liquid” of the present invention includes not only the polishing liquid at the time of using in polishing (specifically, the polishing liquid that is diluted as required), but also includes a concentrated liquid of the polishing liquid. A concentrated liquid or a concentrated polishing liquid refers to a polishing liquid in which the concentration of a solute is regulated to a higher level than that of the polishing liquid when used in polishing, and is used by diluting with water or an aqueous solution at the time of polishing. The dilution rate is typically from 1 to 20 times in volume. The expressions “concentrate” and “concentrated liquid” in the present specification are used as the expressions that are conventionally used to stand for “condensate” or “condensed liquid”, i.e., a more concentrated state than the state when employed, rather than the meanings of general terminology accompanying a physical concentration process such as evaporation, and the like.

Hereinafter, each constituent component of the polishing liquid of the present invention will be explained in greater detail.

Polishing particulate having a hardness of 5 or higher on the Mohs scale, and having a composition containing a main component other than silicon dioxide (SiO₂)

In the present invention, a hard particulate having a hardness of 5 or higher on the Mohs scale is used for the polishing particulate in order to effectively polish a barrier film that is harder than tantalum.

In the present invention, the Mohs scale consists of 10 ranks and is determined based on the hardness of standard materials corresponding to the respective ranks.

Specifically, the standard material having a hardness of 5 on the Mohs scale is apatite (hardness Hk=430), and the material constituting the polishing particulate employed in the present invention is required to have a higher Mohs hardness scale than that of apatite. A hardness of 10 on the Mohs scale represents the hardest rank, and the standard material for this rank is diamond.

Silicon dioxide, which is conventionally employed in polishing particulates, has a hardness of 7 on the Mohs scale (the standard material for a hardness of 7 is quartz), and is harder than apatite having a hardness of 5, and softer than diamond. However, a sufficient polishing rate cannot be obtained when a silica particulate is employed in ruthenium polishing. Although the reason for this is not clear, it is thought that, through an active silanol group on the silica particulate surface, a ruthenium surface can chemically react with other additives such as water, thus changing the Ru surface into a surface that is difficult to polish. This tendency is prominent in a ruthenium film deposited by the ALD system, which can form a film of excellent quality.

The material constituting the polishing particulate preferably has a composition containing a main component selected from the atoms of C, Co, Ni, Fe, Zr, Mg, Y, La, Sn, Ce, Pr, Nd, Al, Ti, Cr, Zn, Si, Mn, Dy, Er, Eu, Gd, Ho, La, Lu, Nd, Sc, Sm, Tb, Tm and Yb. More specific examples of the material include diamond (Mohs hardness: 10; Hk: 7000), γ-alumina (Mohs hardness: 8 to 9; Hk: 1300 to 2000), α-alumina (Mohs hardness: 9; Hk: 1900 to 2500), fused alumina (Mohs hardness: 9; Hk: 2100; as crystal), chromium oxide (Mohs hardness: 8 to 9; Hk: 1200 to 2100), zirconium oxide (Mohs hardness: 7 to 9; Hk: 1200 to 2000), silicon carbide (Mohs hardness: 8 to 10; Hk: 2480), iron oxide (Mohs hardness: 5 to 7; Hk: 1000 to 1600), zinc oxide (Mohs hardness: 5 to 7; Hk: 1000 to 1500), cerium oxide (Mohs hardness: 5 to 7; Hk: 1000 to 1600), silicon nitride (Mohs hardness: 5 to 7; Hk: 1000 to 1500), titanium oxide (Mohs hardness: 5 to 8; Hk: 1000 to 2000), cobalt oxide (Mohs hardness: 5 to 7; Hk: 900 to 1500), and manganese oxide (Mohs hardness: 5 to 7; Hk: 1000 to 1600).

The Mohs hardness of the particulate is determined by scratching the surface of a material to be measured, using a standard material of the Mohs hardness scale, and investigating whether or not a scratch is present on the material to be measured.

In view of an ability to polish Ru at higher rate, among these particulate raw materials, diamond, α-alumina, zirconium oxide, γ-alumina, fused alumina, chromium oxide, silicon carbide, and titanium oxide are preferable.

An average primary particle diameter of the polishing particulate is preferably in a range of 10 nm to 500 nm, and more preferably in a range of 20 nm to 300 nm.

Herein, the average primary particle diameter is a value obtained by observing the polishing particulate with an SEM (scanning electron microscope), and measuring a minimum constituent particle diameter constituting one particle.

The content of the polishing particulate is preferably in a range of 0.1% to 15% by mass, and more preferably in a range of 0.5% to 10% by mass in total solid, with respect to the total mass of the polishing liquid.

In the present invention, in addition to the specific polishing particulate, a polishing particulate other than the specific particulate may be used as long as the effects of the present invention are not adversely affected in any way. In this case, the content of the specific polishing particulate is preferably no less than 50% by mass, and more preferably no less than 80% by mass with respect to the total amount of the polishing particulate. All of the abrasives contained may be the specific polishing particulate.

Examples of the polishing particulate which can be used in combination with the specific polishing particulate in the polishing liquid of the present invention include fumed silica, ceria, alumina, titania, and the like. The average primary particle diameter of these known polishing particulates is preferably in a range of 10 nm to 500 nm, similarly to the diameter of the specific polishing particulate.

Oxidizing Agent

The polishing liquid of the present invention includes a compound capable of oxidizing the metal to be polished (oxidizing agent).

Examples of the oxidizing agent include, for example, hydrogen peroxide, a peroxide, a nitrate, an iodate, a periodate, a hypochlorite, a chlorite, a chlorate, perchlorate, a persulfate, a dichromate, a permanganate, ozonated water, a silver (II) salt and an iron (III) salt. Out of these, hydrogen peroxide is preferably employed.

As the iron (III) salt, an inorganic salt of iron (III) such as iron (III) nitrate, iron (III) chloride, iron (III) sulfate, or iron (III) bromide, and an organic complex salt of iron (III), may preferably be employed.

The amount of the oxidizing agent to be added can be regulated according to the amount of dishing at an early stage of barrier CMP. When the amount of dishing at an early stage of barrier CMP is large, i.e., the desired polishing amount of the wiring material in barrier CMP is not large, the addition amount of the oxidizing agent is preferably small. On the other hand, when the amount of dishing is substantially small and high-rate polishing of the wiring material is desired, the addition amount of the oxidizing agent is preferably large. As mentioned above, the amount of the oxidizing agent being added is preferably modified according to the dishing conditions at an early stage of barrier CMP, and is preferably from 0.01 mol to 1 mol, and more preferably from 0.05 mol to 0.6 mol, with respect to 1 liter of polishing solution when used in polishing.

In the polishing liquid of the present invention, in addition to the above described essential components of the specific polishing particulate and the oxidizing agent, other known additive components may be arbitrarily used depending on the purpose as long as the effects of the present invention are not adversely affected in any way.

These additive components will be described in the following.

Corrosion Inhibiting Agent

The polishing liquid of the present invention includes a corrosion inhibiting agent that inhibits corrosion of the metallic surface by adsorbing to the surface to be polished and forming a film thereon. The corrosion inhibiting agent of the present invention preferably contains a heteroaromatic ring compound containing at least three nitrogen atoms in the molecule and having a condensed ring structure. Here, the “at least three nitrogen atoms” are preferably atoms constituting the condensed ring, and the heteroaromatic compound is preferably benzotriazole or modified compounds thereof obtained by incorporating a substituent group of various kinds into the benzotriazole.

Examples of the corrosion inhibiting agent that can be employed in the present invention include benzotriazole, 1,2,3-benzotriazole, 5,6-dimethyl-1,2,3-benzotriazole, 1-(1,2-dicarboxyethyl)benzotriazole, 1-[N,N-bis(hydroxylethyl)aminomethyl]benzotriazole, and 1 -(hydroxylmethyl)benzotriazole. Out of these, 1,2,3 -benzotriazole, 5,6-methyl-1,2,3-benzotriazole, 1-(1,2-dicarboxyethyl)benzotriazole, 1-[N,N-bis(hydroxylethyl)aminomethyl]benzotriazole, and 1-(hydroxylmethyl)benzotriazole are more preferably selected.

The addition amount of the corrosion inhibiting agent with respect to the amount of polishing liquid used in polishing is preferably from 0.01% by mass to 0.2% by mass, and more preferably from 0.05% by mass to 0.2% by mass. Specifically, the addition amount of the corrosion inhibiting agent is preferably no less than 0.01% by mass from the perspective of preventing expansion of dishing, and is preferably no more than 0.2% by mass from the perspective of storage stability.

Compound having a carboxyl group in the molecule The polishing liquid of the present invention may preferably include a compound having a carboxyl group in the molecule. Although the compound is not particularly limited in any way, as long as the compound has at least one carboxyl group in the molecule, the compound represented by the following Formula (A) is preferably selected in view of improvement of the polishing rate.

Moreover, there are preferably 1 to 4 carboxyl groups in the molecule, and more preferably 1 or 2 carboxyl groups in the molecule, in view of cost efficiency.

R^{A1}—O—R^{A2}—COOH Formula (A)

In Formula (A), R^{A1} and R^{A2} each individually represent a hydrocarbon group, preferably a hydrocarbon group having 1 to 10 carbon atoms.

R^{A1} is a monovalent hydrocarbon group, and preferably an alkyl group having 1 to 10 carbon atoms such as a methyl group, a cycloalkyl group and the like, an aryl group such as a phenyl group and the like, an alkoxy group, or an aryloxy group. R^{A2} is a bivalent hydrocarbon group, and preferably an alkylene group having 1 to 10 carbon atoms such as a methylene group, a cycloalkylene group and the like, an arylene group such as a phenylene group and the like, or an alkyleneoxy group.

The hydrocarbon groups represented by R^{A1} and R^{A2} may also have a substituent group. Examples of the substituent group which can be incorporated include an alkyl group having 1 to 3 carbon atoms, an aryl group, an alkoxy group, a carboxyl group, and the like. In cases where the substituent group is a carboxyl group, the compound has plural carboxyl groups.

Moreover, R^{A1} and R^{A2} may be bound to each other to form a cyclic structure.

Examples of the compound represented by Formula (A) include, for example, 2-furancarboxylic acid, 2,5-furandicarboxylic acid, 3-furancarboxylic acid, 2-tetrahydrofurancarboxylic acid, diglycolic acid, methoxyacetic acid, methoxyphenylacetic acid, and phenoxyacetic acid. Out of these, 2,5-furandicarboxylic acid, 2-tetrahydrofurancarboxylic acid, diglycolic acid, methoxyacetic acid, and phenoxyacetic acid are preferable in view of improvement of the polishing rate.

The addition amount of compound having a carboxyl group (preferably, the compound represented by Formula (A)) with respect to the amount of the polishing liquid used in polishing is preferably from 0.1% by mass to 5% by mass, and more preferably from 0.5% by mass to 2% by mass. Specifically, the amount of the compound having a carboxyl group is preferably no less than 0.1% by mass from the perspective of achieving a sufficient polishing rate, and is preferably no more than 5% by mass from the perspective of preventing excessive dishing.

Organic Acid

The polishing liquid of the present invention may further include an organic acid.

Here, the organic acid has the function of promoting oxidation, adjusting pH, or acting as a buffering agent.

The organic acid is preferably selected from the group consisting of formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylheanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid; salts thereof including ammonium salts, alkali metal salts, sulfate salts, nitrate salts, ammonia salts, and ammonium salts; and mixtures thereof.

Among these, formic acid, malonic acid, malic acid, tartaric acid, and citric acid are preferable for a laminated film having a metal layer of at least one selected from copper, a copper alloy, and oxides of copper or copper alloy.

Examples of the Preferable Organic Salt Include Amino Acid

The amino acid is preferably water-soluble, and more preferably includes at least one amino acid selected from the group consisting of amino acids such as glycine, L-alanine, β-alanine, L-2-aminobutyric acid, L-norvaline, L-valine, L-leucine, L-norleocine, L-isoleucine, L-alloisoleucine, L-phenylalanine, L-proline, sarcosine, L-ornithine, L-lysine, tairome, L-serine, L-threonine, L-allothreonine, L-homoserine, L-tyrosine, 3,5-diiodo-L-tyrosine, β-(3,4-dihydroxyphenyl)-L-alanine, L-thyroxine, 4-hyroxy-L-proline, L-cysteine, L-methionine, L-ethionine, L-lanthionine, L-cystathionine, L-cystine, L-cysteic acid, L-aspartic acid, L-glutamic acid, S-(carboxymethyl)-L-cystine, 4-aminobutyric acid, L-asparagine, L-gluamine, azaserine, L-arginine, L-canavanine, L-citrulline, δ-hydroxy-L-lysine, creatine, L-kynurenine, L-histidine, 1-methyl-L-histidine, 3-methyl-L-histidine, ergothioneine, L-tryptophan, actinomycin C1, apamine, angiotensin I, angiotensin II, antipine, and the like.

Among these, malic acid, tartaric acid, citric acid, glycine and glycolic acid are particularly preferable in view of effective suppression of the etching rate while maintaining a practical CMP rate.

The addition amount of the organic acid with respect to 1 liter of the polishing liquid when used in polishing is preferably from 0.0005 mol to 0.5 mol, more preferably from 0.005 mol to 0.3 mol, and particularly preferably from 0.01 mol to 0.1 mol. That is, the addition amount of the organic acid with respect to 1 liter of the polishing liquid when used in polishing is preferably no more than 0.5 mol in view of effective suppression of etching, and is preferably no less than 0.0005 mol from the perspective of achieving sufficient effects.

Cationic Quaternary Ammonium Salt Compound

From the perspective of improvements in the planarizing properties and dispersion stability of the particulate, a cationic quaternary ammonium salt compound is preferably added to the polishing liquid of the present invention.

The cationic quaternary ammonium salt compound used herein is not particularly limited in any way, as long as the compound has a configuration including one or two quaternary nitrogens within the molecular structure. In view of fewer inhibitory effects on film polishing performance, the cationic quaternary ammonium salt compound is preferably a cation represented by the following Formula (1) or Formula (2).

Hereafter, the compound represented by the following Formula (1) or Formula (2) will be explained.

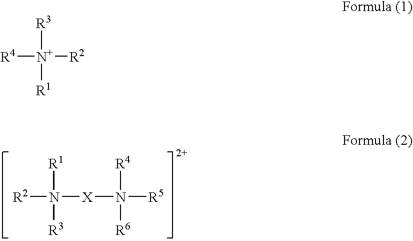

In Formula (1), each of R¹ to R⁴ represents the same hydrocarbon group having 1 to 18 carbon atoms. Examples of the hydrocarbon group represented by R¹ to R⁴ include an alkyl group, an aryl group, and a phenyl group. Among these, an alkyl group having a straight chain structure of 1 to 5 carbon atoms is preferable.

Examples of the compound represented by Formula (1) include tetramethyl ammonium, tetraethyl ammonium, tetrapropyl ammonium, tetrabutyl ammonium, or tetrapentyl ammonium.

In Formula (2), R¹ to R⁶ each independently represent an alkyl group having 1 to 20 carbon atoms, an alkenyl group having 1 to 20 carbon atoms, a cycloalkyl group, an aryl group, or an aralkyl group. Moreover, a pair or pairs of the groups R¹ to R⁶ may be bonded to each other to form a cyclic structure.

Examples of the alkyl group having 1 to 20 carbon atoms represented by R¹ to R⁶ include a methyl group, an ethyl group, a propyl group, a butyl group, a pentyl group, a hexyl group, a heptyl group, and an octyl group. Among these, a methyl group, an ethyl group, a propyl group, and a butyl group are preferable.

Moreover, as the alkenyl group represented by R¹ to R⁶, an alkenyl group having 2 to 10 carbon atoms is preferable, and examples thereof include an ethynyl group, a propyl group, and the like.

Examples of the cycloalkyl group represented by R¹ to R⁶ include a cyclohexyl group, a cyclopentyl group, and the like. Among these a cyclohexyl group is preferable.

Examples of the aryl group represented by R¹ to R⁶ include a butynyl group, a pentynyl group, a hexynyl group, a phenyl group, a naphthyl group, and the like. Among these, a phenyl group is preferable.

Examples of the aralkyl group represented by R¹ to R⁶ include a benzyl group.

Each group represented by R¹ to R⁶ may further have a substituent group. Examples of the substituent group which can be incorporated include a hydroxyl group, an amino group, a carboxyl group, a heterocyclic group, a pyridinium group, an aminoalkyl group, a phosphoric group, an imino group, a thiol group, a sulfo group, a nitro group, and the like.

In Formula (2), X represents an alkylene group having 1 to 10 carbon atoms, an alkenylene group, a cycloalkylene group, an arylene group, or a combination of two or more thereof.

In addition to the organic linking group, the linking group represented by X may also include a linking group such as —S—, —S(═O)₂—, —O—, or —C(═O)— within a chain thereof.

Preferable examples of the alkylene group having 1 to 10 carbon atoms include a methylene group, an ethylene group, a propylene group, a butylene group, a pentylene group, a hexylene group, a heptylene group, an octylene group, and the like. Among these, an ethylene group and a pentylene group are preferable.

Examples of the alkenylene group include an ethynylene group, a propynylene group and the like. Among these, a propynylene group is preferable.

Examples of the cycloalkylene group include a cyclohexylene group, a cyclopentylene group, and the like. Among these, a cyclohexylene group is preferable.

Examples of the arylene group include a phenylene group and a naphthylene group. Among these, a phenylene group is preferable.

Each of the linking groups may further have a substituent group. Examples of a substituent group which can be incorporated include a hydroxyl group, an amino group, a sulfonyl group, a carboxyl group, a heterocyclic group, a pyridinium group, an aminoalkyl group, a phosphoric group, an imino group, a thiol group, a sulfo group, a nitro group, and the like.

In the polishing liquid of the present invention, the addition amount of the cationic quaternary ammonium salt compound is preferably from 0.00001% by mass to 10% by mass, and more preferably from 0.0001% by mass to 1% by mass based on the mass of the polishing liquid when used in polishing. Specifically, the content of the quaternary ammonium salt compound is preferably no less than 0.00001% by mass in view of achieving a stable dispersion of the particulate, and is preferably no more than 10% by mass in view of achieving a better planarizing property.

Surfactant

The polishing liquid of the present invention may include a surfactant.

By regulating the type or amount of the surfactant employed in the present invention, the polishing rate of the insulation layer can be controlled and improved.

Among the surfactant, a compound represented by the following Formula (3) is preferable in view of improving the polishing rate in polishing the insulation layer, while a compound represented by the following Formula (4) is preferable in view of controlling the polishing rate in polishing the insulation layer.

R—SO₃⁻ Formula (3)

In Formula (3), R represents a hydrocarbon group, preferably a hydrocarbon group having 6 to 20 carbon atoms.

Specifically, for example, an alkyl group and an aryl group having 6 to 20 carbon atoms such as a phenyl group, a naphthyl group and the like, is preferable. Moreover, this alkyl group or aryl group may further include a substituent group such as an alkyl group and the like.

Specific examples of the compound represented by Formula (3) include compounds such as decyl benzenesulfonic acid, dodecyl benzenesulfonic acid, tetradecyl benzenesulfonic acid, hexadecyl benzenesulfonic acid, dodecyl naphthalenesulfonic acid, tetradecyl naphthalenesulfonic acid, and the like.

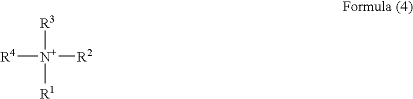

In Formula (4), R¹ to R⁴ each individually represent a hydrocarbon group having 1 to 18 carbon atoms. However, the case where all of the R¹ to R⁴ are the same hydrocarbon group is excluded from Formula (4).

Examples of the hydrocarbon group represented by R¹to R⁴ include an alkyl group, an aryl group, a phenyl group, and the like. Among these, an alkyl group having a straight or branched chain structure and having 1 to 20 carbon atoms is preferable.

Moreover, pair(s) of the groups R¹ to R⁴ may be bound to each other to form a cyclic structure, such as a pyridine structure, a pyrrolidine structure, a piperidine structure, or a pyrrole structure.

Examples of the specific compound represented by Formula (4) include, for example, compounds such as lauryl trimethyl ammonium, lauryl triethyl ammonium, stearyl trimethyl ammonium, palmityl trimethyl ammonium, octyl trimethyl ammonium, dodecyl pyridinium, decyl pyridinium, or octyl pyridinium.

Examples of an anionic surfactant other than those represented by Formulae (3) or (4) include a carboxylate, a sulfate salt, and a phosphate salt.

More specifically, preferable examples of the carboxylate include soap, an N-acrylamino acid salt, a polyoxyethylene alkyl ether carboxylate or a polyoxypropylene alkyl ether carboxylate, an acylated peptide; preferable examples of the sulfate salt include a sulfated oil, an alkyl sulfate, an alkyl ether sulfate, a polyoxyethylene or polyoxypropylene alkyl allyl ether sulfate, an alkyl amide sulfate; and preferable examples of the phosphate salt include an alkyl phosphate, a polyoxyethylene or polyoxypropylene alkyl allyl ether phosphate.

The total addition amount of the surfactant with respect to 1 liter of polishing liquid when used in polishing is preferably from 0.001 g to 10 g, more preferably from 0.01 g to 5 g, and even more preferably from 0.01 g to 1 g. Specifically, the amount of the surfactant being added is preferably no less than 0.01 g from the perspective of achieving sufficient effects, and preferably no more than 1 g from the perspective of preventing a decrease in the CMP rate.

Hydrophilic Polymer

The polishing liquid of the present invention may further contain a hydrophilic polymer.

By regulating the kind or amount of the hydrophilic polymer employed in the present invention, the polishing rate of the insulating layer can be controlled or improved.

Examples of the hydrophilic polymer employed in the present invention include ethers such as polyethylene glycol, polypropylene glycol, polytetramethylene glycol, polyethylene glycol alkyl ether, polyethylene glycol alkenyl ether, alkyl polyethylene glycol, alkylpolyethylene glycol alkyl ether, alkylpolyethylene glycol alkenyl ether, alkenylpolyethylene glycol, alkenylpolyethylene glycol alkyl ether, alkenylpolyethylene glycol alkenyl ether, polypropylene glycol alkyl ether, polypropylene glycol alkenyl ether, alkylpolypropylene glycol, alkylpolypropylene glycol alkyl ether, alkylpolypropylene glycol alkenyl ether, alkenylpolypropylene glycol, alkenylpolypropylene glycol alkyl ether or alkenylpolypropylene glycol alkenyl ether; polysaccharides such as carboxymethylcellulose, curdlan or pullulan; amino acid salts such as a glycine ammonium salt or a glycine sodium salt; polycarboxylic acid and salts thereof, such as polyaspartic acid, polyglutamic acid, polylysine, polymalic acid, polymethacrylic acid, a polymethacrylic acid ammonium salt, a polymethacrylic acid sodium salt, polymaleic acid, polyitaconic acid, polyfumaric acid, poly(p-styrene carboxylic acid), polyacrylic acid, polyacrylamide, aminopolyacrylamide, a polyacrylic acid ammonium salt, a polyacrylic acid sodium salt, a polyamide acid salt (polyamic acid), or polyglyoxylic acid; and a vinyl-based polymer, such as polyvinyl alcohol, polyvinylpyrrolidone or polyacrolein.

The total addition amount of the hydrophilic polymer with respect to 1 liter of polishing liquid when used in polishing is preferably 0.001 g to 10 g, more preferably 0.01 g to 1 g, and even more preferably 0.02 g to 0.5 g.

Specifically, the amount of the surfactant and/or the hydrophilic polymer being added is preferably no less than 0.001 g in view of achieving sufficient effects, and preferably no more than 10 g in view of preventing a decrease in the CMP rate. Moreover, the weight-average molecular weight of the surfactant and/or the hydrophilic polymer is preferably 500 to 100000, and more preferably 2000 to 50000. The hydrophilic polymer may be used singly, or in combination of two or more kinds thereof. Different kinds of the surfactant may be used in combination.

Adjustment of pH of Polishing Liquid

The polishing liquid of the present invention preferably has a pH in the range of 2.0 to 12.0. By regulating the pH of the polishing liquid within this range, the polishing rate of the interlayer can be regulated more notably.

In order to regulate the pH within the above-mentioned desired range, an alkali/acid or a buffering agent can be employed. The polishing liquid of the present invention achieves a superior effect when the pH is within the above-mentioned range.

Examples of the alkali/acid or the buffering agent preferably include ammonia; an organic ammonium hydroxide, such as ammonium hydroxide or tetramethyl ammonium hydroxide; a non-metallic alkali agent such as alkanol amines like, diethanol amine, triethanol amine, or triisopropanol amine; an alkali metal hydroxide, such as sodium hydroxide, potassium hydroxide, or lithium hydroxide; an inorganic acid, such as nitric acid, sulfuric acid, or phosphoric acid; a carbonate, such as sodium carbonate; a phosphate, such as trisodium phosphate; a borate; a tetraborate; a hydroxybenzoate; and the like. Among these, ammonium hydroxide, potassium hydroxide, lithium hydroxide, and tetramethyl ammonium hydroxide are particularly preferable.

The addition amount of the alkali/acid or the buffering agent may be determined to any amount as long as it maintains the pH within the desired range, and is preferably 0.0001 mol to 1.0 mol, and more preferably 0.003 mol to 0.5 mol, with respect to 1 liter of the polishing liquid when used in polishing.

Chelating Agent

The polishing liquid of the present invention may preferably include a chelating agent (i.e., a water softener), when necessary, in order to reduce adverse effects of a polyvalent metal ion incorporated therein, and the like.

Examples of the chelating agent include a general-purpose water softener, or an analogous compound thereof, which is a calcium or magnesium precipitation inhibiting agent, for example, nitrilotriacetic acid; diethylene triamine penta-acetic acid; ethylene diamine tetra-acetic acid; N,N,N-trimethylene phosphonic acid; ethylene diamine-N,N,N′,N′-tetramethylene sulfonic acid; trans-cyclohexanediamine tetraacetic acid; 1,2-diaminopropane tetraacetic acid; glycol ether diamine tetraacetic acid; ethylenediamine ortho hydroxylphenylacetic acid; ethylene diamine succinic acid (SS); N-(2-carboxylate ethyl)-L-asparagine acid; β-alanine diacetic acid; 2-phosphonobutane-1,2,4-tricarboxylic acid; 1-hydroxyethylidene-1,1-diphosphonic acid; N,N′-bis(2-hydroxybenzyl)ethylenediamine-N,N′-diacetic acid; and 1,2-dihydroxybenezene-4,6-disulfonic acid, and the like.

As necessary, two or more kinds of chelating agents may be used in combination.

The amount of the chelating agent being added can be determined at any amount as long as it is sufficient to trap metal ions, such as polyvalent metal ions, and may be, for example, 0.0003 mol to 0.07 mol with respect to 1 liter of polishing liquid when used in polishing.

The polishing liquid of the present invention, typically, is suitable for polishing of a barrier layer composed of a barrier metal material for preventing copper diffusion, the barrier layer being placed between wiring lines composed of a copper metal and/or a copper alloy, and an interlayer insulation film.

Barrier Metal Material

Rruthenium is used as the material constituting the barrier layer, which is the object to be polished by using the polishing liquid of the present invention, in view of being a low resistance metal and having superior barriering property even when formed as a thin layer. Ruthenium may be used alone, or used as an alloy with another metal, or as a modified compound such as ruthenium oxide or ruthenium nitride.

The ruthenium-containing barrier layer of the present invention may be formed by any given method. The polishing liquid of the invention can be applied to any film obtained by known film formation methods such as a sputtering system, an ALD system, or a PVD (Physical Vapor Deposition) system. The polishing liquid of the present invention exhibits remarkable effects when applied to a ruthenium film formed by the ALD system, while a superior polishing rate cannot obtained when a normal polishing liquid is applied.

Interlayer Insulation Film

Examples of the interlayer insulation film which can be polished with the polishing liquid of the present invention include, in addition to conventionally employed interlayer insulation films such as those containing tetraethoxysilane (TEOS), an interlayer insulation film composed of a material having a specific inductive capacity of as low as about 3.5 to 2.0, such as those containing an organic polymere, a silicon oxycarbide (SiOC) compound, or fluorine-doped silicon dioxide (SiOF) compound, which are conventionally referred to as Low-k films.

The specific inductive capacity of a general dielectric material such as TEOS is in the range of about 3.8 to about 4.2.

As the interlayer insulation film having low specific inductive capacity, an insulating film having an organic siloxane structure and a specific inductive capacity of 3.0 or less is preferable.

A material that forms the insulating film having an organic siloxane structure and a specific inductive capacity of 3.0 or less may be employed as the material used for the formation of an interlayer insulation film having low specific inductive capacity without any particular limitation

Preferable examples of the material include organic materials having an organic siloxane structure such as SiOC (for example, SiOC containing a plurality of Si—C bonds or Si—H bonds), methylsesquioxane (MSQ), and the like.

Examples of the organic siloxane structure include the structure represented by the following Formula (5).

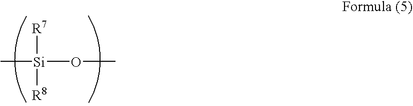

In Formula (5), R⁷ represents a hydrogen atom, a hydrocarbon group or OR⁹, and R⁸ represents a hydrocarbon group or OR¹⁰. R⁹ and R¹⁰ each independently represents a hydrocarbon group.

In Formula (5), specific examples of the hydrocarbon group represented by R⁷ to R¹⁰ include an aliphatic hydrocarbon group and an aromatic hydrocarbon group.

Examples of the material that can be employed in formation of the insulating film having low specific inductive capacity include an SiOC material such as HSG-R7 (trade name, manufactured by Hitachi Chemical Company, Ltd., specific inductive capacity: 2.8), BLACKDIAMOND (trade name, manufactured by Applied Materials, Inc., specific inductive capacity: 2.4 to 3.0), p-MTES (trade name, manufactured by Hitachi Kaihatsu, specific inductive capacity: 3.2), CORAL (trade name, manufactured by Novellus Systems, Inc, specific inductive capacity: 2.4 to 2.7), or AURORA (trade name, manufactured by Japan AMS, specific inductive capacity: 2.7); and a methylsilsesquioxane (MSQ) material, such as OCDT-9 (trade name, manufactured by Tokyo Ohka Kogyo Ltd., specific inductive capacity: 2.7), LKB-T200 (trade name, manufactured by JSR, specific inductive capacity: 2.5 to 2.7), HOSP (trade name, manufactured by Honeywell Electronic Materials, specific inductive capacity: 2.5), HSG-RZ25 (trade name, manufactured by Hitachi Chemical Company, Ltd., specific inductive capacity: 2.5), OCLT-31 (trade name, manufactured by Tokyo Ohka Kogyo Ltd., specific inductive capacity: 2.3), LKD-T400 (trade name, manufactured by JSR, specific inductive capacity: 2.0 to 2.2), HSG-6211X (trade name, manufactured by Hitachi Chemical Company, Ltd., specific inductive capacity: 2.1), ALCAP-S (trade name, manufactured by Asahi Chemical Industry Co., Ltd., specific inductive capacity: 1.8 to 2.3), OCLT-77 (trade name, manufactured by Tokyo Ohka Kogyo Ltd., specific inductive capacity: 1.9 to 2.2), HSG-6211X (trade name, manufactured by Hitachi Chemical Company, Ltd., specific inductive capacity: 2.4), or silica aerogel (trade name, manufactured by Kobe Steel Ltd., specific inductive capacity: 1.1 to 1.4), although the present invention is not limited to these examples.

The material employed in formation of the insulating film having low specific inductive capacity may be used alone, or in combination of plural kinds thereof. Moreover, the material may have fine vacancies.

Examples of a method of forming the insulating film of the present invention include a plasma CVD method, a spin coating method, and the like.

The specific inductive capacity of the interlayer insulation film having low specific inductive capacity of the present invention is preferably no more than 3.0, and more preferably 1.8 to 2.8.

The specific inductive capacity of a plain film can be measured by a measuring method using a mercury probe. The specific inductive capacity of the insulating film on which wiring is provided can be measured using an LCR meter such as 4284A PRECISION LCR METER (trade name, manufactured by Agilent Technologies).

Raw Material for Forming Wiring Lines

The surface to be polished in the present invention preferably has wiring lines containing copper metal and/or a copper alloy, such as one applied to semi-conductor devices such as LSI chips. In particular, copper alloys are preferable as the raw material for such wiring lines. Moreover, among these, a copper alloy which includes silver is preferable.

Furthermore, the amount of silver included in the copper alloy is preferably no more than 40% by mass, more preferably no more than 10% by mass, even more preferably no more than 1% by mass, and the most superior effects can be achieved at an amount in the range of 0.00001% to 0.1% by mass with respect to the total amount of the copper alloy.

Thickness of Wiring Lines

When the object for polishing in the present invention is applied to DRAM type devices, the wiring lines preferably have a thickness of, in half-pitch, no more than 0.15 μm, more preferably no more than 0.10 μm, and even more preferably no more than 0.08 μm.

On the other hand, when the object for polishing is applied to micro processing unit (MPU) type devices, the wiring lines preferably have a thickness of no more than 0.12 μm, more preferably no more than 0.09 μm, and even more preferably no more than 0.07 μm.

The polishing liquid of the present invention exhibits particularly superior effects to a surface having this type of wiring lines.

Polishing Method

The polishing liquid of the invention may be:

(1) formed to be in the form of a concentrated solution, which is diluted by adding water or an aqueous solution when employed;

(2) prepared by mixing aqueous solutions respectively containing the components of the polishing liquid, as mentioned below, and diluting by adding water when necessary; or (3) formed to be in the form of a liquid that can be used as is.

Any of the polishing liquids (1) to (3) may be applied to the polishing method employing the polishing liquid of the present invention.

This polishing method is a method in which a polishing liquid is supplied onto a polishing pad placed on a polishing platen, the polishing pad is brought into contact with a surface to be polished, and the surface to be polished and polishing pad are set into relative motion.

A conventional polishing device having a holder for holding an object having a surface to be polished (for example, a wafer in which a film of conductive material is formed) and a polishing platen onto which a polishing pad is attached (equipped with a variable-speed motor and the like) may be used as the device employed in polishing. As the polishing pad, conventional non-woven fabric, a polyurethane foam, a porous fluorocarbon resin, and the like, may be employed without being particularly limited. The rotation speed of the polishing platen is not particularly limited in any way, but is preferably as low as 200 rpm or less, so that the object to be polished does not deviate from the platen. Moreover, the contact pressure (polishing pressure) from the polishing pad to the object having the surface to be polished (a film to be polished) is preferably from 0.69 kPa to 20.68 kPa (from 0.1 psi to 3 psi), and more preferably from 3.45 kPa to 20.68 kPa (from 0.5 psi to 3.0 psi) , in order to satisfy in-plane uniformity and pattern flatness of the substrate.

During polishing, the polishing liquid is continuously supplied onto the polishing pad by a pump and the like.

Once the substrate is completely polished, it is washed thoroughly with running water, and then dried by removing the water droplets on the polished surbstrate with a spin drier and the like.

When a concentrated liquid of the polishing liquid is diluted, as described in the method (1), the aqueous solution indicated below can be employed for diluting the concentrated solution. The aqueous solution is water in which at least one component of an oxidizing agent, an organic acid, an additive agent, and a surfactant is preliminarily included, such that the total amount of the components in the aqueous solution and in the concentrated liquid is equal to that in the resulting polishing liquid when used in polishing (liquid for use).

Accordingly, when the polishing liquid is prepared by diluting a concentrated solution, components that do not readily dissolve can be compounded subsequently, in the form of an aqueous solution. Consequently, a concentration liquid can be prepared to have an even higher degree of concentration.

Moreover, as the method of diluting the concentrated solution by adding water or an aqueous solution, a method may also be employed in which a pipe for supplying a concentrated polishing liquid and a pipe for supplying water or an aqueous solution are joined together in midstream, and thereby supplying a liquid for use of the polishing liquid that has been mixed and diluted onto the polishing pad. The mixing of the concentrated solution and the water or aqueous solution may be performed by a conventionally employed method, such as: a method in which liquids are collision-mixed by allowing the liquids to pass through a narrow path while applying pressure; a method in which a filler, such as glass pipes, is packed within the pipes, and branching/separation and convergence of the liquid streams are repeated; and a method in which a vane that is revolved by force is provided within the pipes.

The supplying rate of the polishing liquid is preferably from 10 ml/min to 1000 ml/min, and more preferably from 170 ml/min to 800 ml/min, in order to satisfy in-plane uniformity and pattern flatness of the surface to be polished.

Moreover, as the method of polishing while continuing to dilute the concentrated solution with water or an aqueous solution, there is a method in which the pipe supplying the polishing liquid and the pipe supplying water or the aqueous solution are separately provided, and predetermined amounts of the liquid and the water or aqueous solution is supplied onto the polishing pad from respective pipes, and polishing is carried out while mixing the liquid and the water or aqueous solution by means of the relative motion between the polishing pad and the surface to be polished. Furthermore, a polishing method may also be employed in which predetermined amounts of the concentrated liquid and the water or aqueous solution are mixed in a single container, and then the mixture is supplied onto the polishing pad.

Moreover, a polishing method may also be used in which the components which must be included in the polishing liquid are divided into at least two constituent components, and the constituent components are diluted, when employed, by adding water or an aqueous solution and supplied onto the polishing pad placed on the surface of the polishing platen, and then brought into contact with the surface to be polished, thereby performing polishing by relatively moving the surface to be polished and the polishing pad.

For example, the components may be divided in such a manner that an oxidizing agent is provided as the constituent component (A), while an organic acid, additive agent, surfactant and water are provided as the constituent component (B), and at the time of usage, the constituent components (A) and (B) are diluted with water or an aqueous solution.

Alternatively, the additive agents having low solubility may be separated to be included in either of the two constituent components (A) and (B), for example, in such a manner that the oxidizing agent, additive agent, and surfactant are provided as constituent component (A), while the organic acid, additive agent, surfactant, and water are provided as constituent component (B), and at the time of usage, the constituent components (A) and (B) are diluted with water or an aqueous solution.

In such exemplified cases, three pipes are required in order to supply constituent component (A), constituent component (B), and water or an aqueous solution, respectively. The dilution and mixing may be carried out by a method in which the three pipes are joined to form a single pipe from which the polishing liquid is supplied onto the polishing pad, and mixing is performed within the pipe. In this case, it may also be possible that two of the pipes are joined first, and then the last pipe is joined, subsequently. This method is, specifically, that the constituent component containing the additive agent having low solubility and other constituent component(s) are mixed first, and after the mixture has passed through a long distance to ensure enough time for the additive agent to dissolve, water or an aqueous solution is supplied at the position where the last pipe is joined together.

Other mixing methods include a method in which three of the pipes are directly lead to the polishing pad, respectively, and mixing is carried out while the polishing pad and the surface to be polished are relatively moving; a method in which three constituent components are mixed in a single container, and the diluted polishing liquid is supplied onto the polishing pad; and the like.

In the polishing methods, the temperature of the constituent components may be regulated such that the constituent component including an oxidizing agent has a temperature of no more than 40° C., while other constituent components are heated to a temperature ranging from room temperature to 100° C., and at the time of mixing those constituent components or adding water or an aqueous solution to dilute, the resulting solution has a temperature of no more than 40° C. This method is effective for elevating the solubility of the raw material having a low solubility in the polishing liquid, by utilizing a phenomenon that the solubility is elevated by increasing the temperature thereof.

The raw material that is dissolved by heating the other constituent components to a temperature ranging from room temperature to 100° C. precipitates in the solution as the temperature decreases. Therefore, when the other constituent component(s) are employed in a low temperature state, pre-heating of the precipitated components must be performed. The heating can be achieved by applying a process in which the other constituent component(s) that have been heated to dissolve the raw material are delivered; or a process in which the liquid containing a precipitated material is agitated and delivered, while the pipe is heated to dissolve the material. If the heated other constituent component(s) increase the temperature of the constituent component(s) including the oxidizing agent up to 40° C. or more, the oxidizing agent may disintegrate. Therefore, the temperature of the mixture of the constituent component(s) including the oxidizing agent and the other constituent component(s) is preferably 40° C. or less.

As mentioned above, in the present invention, the components of the polishing liquid may be divided into at least two components, and supplied onto the surface to be polished. In such cases, it is preferable that the components are divided into a component containing the organic acid and a component including the oxide. Moreover, it may also be possible that the concentrated solution is provided as the polishing liquid, and the dilution water is separately supplied onto the surface to be polished.

In the present invention, in cases where a method in which the polishing liquid is divided into at least two groups of components and supplied onto the surface to be polished is applied, the supplying amount thereof refers to the sum of the amounts supplied from each pipe.

Pad

As the polishing pad for polishing that can be employed in the polishing method of the present invention, either a non-foam structured pad or a foam structured pad may be applicable. The former employs a hard synthetic resin bulk material, such as a plastic plate, to form the pad. The latter further includes three types of the pad: an independent foam (dry foam type), a continuous foam (wet foam type), and a two-layer composite (laminated type). In particular, the two-layer foam composite is preferable. The foaming may be either uniform or non-uniform.

Furthermore, the pad may include abrasive grains which are conventionally employed in polishing (for example, those composed of ceria, silica, alumina, a resin, and the like). Moreover, the hardness of the pad may be either hard or soft. In the laminated type, it is preferable that each respective layer have a different hardness. Non-woven fabric, artificial leather, polyamide, polyurethane, polyester, polycarbonate and the like can be exemplified as the preferable materials. Moreover, lattice grooves, holes, concentric grooves, helical grooves, and the like may be formed on the surface of the pad to be in contact with the surface to be polished.

Wafer

The diameter of the wafer as the object for polishing in a CMP process employing the polishing liquid of the present invention is preferably no less than 200 mm, and in particular, preferably no less than 300 mm. When the diameter is no less than 300 mm, effects of the present invention can be remarkably exhibited

Polishing Device

The device employing the polishing liquid of the present invention in a polishing process is not particularly limited in any way, and may include Mirra Mesa CMP and Reflexion CMP (both trade names, manufactured by Applied Materials, Inc.), FREX 200 and FREX 300 (both trade names, manufactured by Ebara Corporation), NPS 3301 and NPS 2301 (both trade names, manufactured by Nikon Corporation), A-FP-310A and A-FP-210A (both trade names, manufactured by Tokyo Seimitsu, Co., Ltd.), 2300 TERES (trade name, manufactured by Lam Research, Co., Ltd.), Momentum (trade name, manufactured by SpeedFam-IPEC, Inc.), and the like.

### EXAMPLES

Hereinafter, the present invention will be explained in greater detail with reference to the following Examples. However, the present invention is not specifically limited to the Examples.

### Example 1

A polishing liquid having the following Formulation (1) was prepared and a polishing experiment was conducted using thereof.

### Formulation (1)

α-alumina (Mohs hardness: 8 to 9, particle diameter 50 nm) (Polishing particulate): 100 g/l
Citric acid (manufactured by Wako Pure Chemical Industries, ltd.) (Organic acid): 15 g/l
Benzotriazole (BTA) (Corrosion inhibiting agent): 1 g/l

Pure water was added to bring the total volume of the polishing liquid to 1000 ml.

As oxidizing agent, 20 ml of hydrogen peroxide was added to the polishing liquid per 1 liter thereof.

The pH of the obtained polishing liquid was adjusted to 5.0 with ammonia water and nitric acid.

Evaluation Method

MA-300D (trade name, manufactured by Musashino Denshi) was employed as the polishing device, and each of the wafer films shown in the followings were polished while providing a slurry, under the following conditions:

Number of table rotation: 112 rpm

Number of head rotation: 113 rpm

Polishing pressure: 9.19 kPa (1.33 psi)

Polishing pad: IC1400 XY-K-Pad (trade name, manufactured by Rodel Nitta Company)

Polishing liquid supply rate: 50 ml/min

Object to be Polished

An 8 inch wafer having an Ru film formed on an Si substrate by an ALD processor (trade name ALDINNA, manufactured by Hitachi Kokusai Electric Inc.) was employed as the object to be polished. The 8 inch wafer was cut into a 6 cm×6 cm piece to obtain a cut wafer, which was used as the object to be polished.

Evaluation of Polishing Rate

The polishing rate was determined by measuring the film thicknesses of the Ru film (barrier layer), at time points before and after performing CMP, and calculating using the following equation.

Polishing rate (nm/min)=(film thickness before polishing−film thickness after polishing)/(polishing time)

The results obtained are shown in Table 1.

### Examples 2 to 45 and Comparative Examples 1 to 10

The polishing experiments were conducted under the same conditions as those of Example 1, except that the polishing liquid which was prepared by modifying the composition (1) of Example 1 into the compositions described in the below-mentioned Tables 1 to 6 were used. The results obtained are indicated in Tables 1 to 6.

The names of the compounds abbreviated in the above Tables 1 to 6 are indicated below.

TBA: tetrabutyl ammonium nitrate (cationic quaternary ammonium salt compound);

TMA: tetramethyl ammonium nitrate (cationic quaternary ammonium salt compound);

HMC: hexamethonium chloride (cationic quaternary ammonium salt compound);

BTA: 1,2,3-benzotriazole (corrosion inhibiting agent);

HMBTA: 1-(hydroxymethyl)benzotriazole (corrosion inhibiting agent);

DCEBTA: 1-(1,2-dicarboxyethyl)benzotriazole (corrosion inhibiting agent);

DBSA: dodecylbenzenesulfonic acid (surfactant); and

LTM: lauryltrimethylammonium nitrate (surfactant)

TABLE 1

| | Polishing particulate | | Compound having carboxyl | Oxidizing | Other | | Ru polishing |
|---|---|---|---|---|---|---|---|
| | (content; particle | Corrosion inhibiting | group in the molecule | agent | component | | rate |
| | diameter) | agent (content) | (content) | (content) | (content) | pH | (nm/min) |
| Example 1 | A-2 | BTA | Citric acid | Hydrogen | TBA additive | 5.0 | 10 |
| | (100 g/L; 50 nm) | (1 g/L) | (15 g/L) | peroxide | (1 g/L) | | |
| | | | | (20 ml/L) | | | |
| Example 2 | A-1 | BTA | 2-Tetrahydrofurancarboxylic | Hydrogen | — | 3.5 | 15 |
| | (100 g/L; 150 nm) | (1 g/L) | acid | peroxide | | | |
| | | | (15 g/L) | (20 ml/L) | | | |
| Example 3 | A-2 | BTA | Lactic acid | Hydrogen | — | 8.5 | 7 |
| | (100 g/L; 80 nm) | (1 g/L) | (15 g/L) | peroxide | | | |
| | | | | (20 ml/L) | | | |
| Example 4 | A-3 | DCEBTA | Diglycolic acid | Ammonium | TMA additive | 5.0 | 10 |
| | (100 g/L; 100 nm) | (1 g/L) | (15 g/L) | persulfate | (1 g/L) | | |
| | | | | (15 g/L) | | | |
| Example 5 | A-4 | BTA | Methoxy acetic acid | Hydrogen | DBSA | 6.5 | 15 |
| | (100 g/L; 60 nm) | (1 g/L) | (15 g/L) | peroxide | (0.03 g/L) | | |
| | | | | (20 ml/L) | | | |

TABLE 2

| | Polishing particulate | | Compound having carboxyl | Oxidizing | Other | | Ru polishing |
|---|---|---|---|---|---|---|---|
| | (content; particle | Corrosion inhibiting | group in the molecule | agent | component | | rate |
| | diameter) | agent (content) | (content) | (content) | (content) | pH | (nm/min) |
| Example 6 | A-5 | BTA | Tartaric acid | Hydrogen | Polyacrylic | 7.5 | 12 |
| | (100 g/L; 50 nm) | (1 g/L) | (15 g/L) | peroxide | acid | | |
| | | | | (20 ml/L) | (1 g/L) | | |
| Example 7 | A-1 | BTA | Diglycolic acid | Hydrogen | TMA additive | 2.5 | 18 |
| | (100 g/L; 200 nm) | (1 g/L) | (15 g/L) | peroxide | (1 g/L) | | |
| | | | | (20 ml/L) | | | |
| Example 8 | A-3 | BTA | Methoxyacetic acid | Hydrogen | HMC additive | 2.0 | 6 |
| | (100 g/L; 100 nm) | (1 g/L) | (15 g/L) | peroxide | (1 g/L) | | |
| | | | | (20 ml/L) | | | |
| Example 9 | A-6 | HMBTA | Citric acid | Hydrogen | — | 8.0 | 10 |
| | (100 g/L; 150 nm) | (1 g/L) | (15 g/L) | peroxide | | | |
| | | | | (20 ml/L) | | | |
| Example | A-7 | BTA | Lactic acid | Hydrogen | — | 4.0 | 16 |
| 10 | (100 g/L; 100 nm) | (1 g/L) | (15 g/L) | peroxide | | | |
| | | | | (20 ml/L) | | | |

TABLE 3

| | Polishing particulate | | Compound having carboxyl | Oxidizing | | | Ru polishing |
|---|---|---|---|---|---|---|---|
| | (content; particle | Corrosion inhibiting | group in the molecule | agent | Other component | | rate |
| | diameter) | agent (content) | (content) | (content) | (content) | pH | (nm/min) |
| Example | A-8 | BTA | Glycolic acid | Ammonium | Polyoxyethylene | 3.5 | 12 |
| 11 | (100 g/L; 200 nm) | (1 g/L) | (15 g/L) | persulfate | lauryl ether | | |
| | | | | (15 g/L) | (0.05 g/L) | | |
| Example | A-9 | BTA | 2-Tetrahydrofurncarboxylic | Hydrogen | DBSA | 5.0 | 15 |
| 12 | (100 g/L; 300 nm) | (1 g/L) | acid | peroxide | (0.03 g/L) | | |
| | | | (15 g/L) | (20 ml/L) | | | |
| Example | A-10 | DBTA | Diglycolic acid | Hydrogen | — | 3.5 | 10 |
| 13 | (100 g/L; 20 nm) | (1 g/L) | (15 g/L) | peroxide | | | |
| | | | | (20 ml/L) | | | |
| Example | A-1 | DCEBTA | Malic acid | Hydrogen | Polyoxyethylene | 5.0 | 16 |
| 14 | (100 g/L; 300 nm) | (1 g/L) | (15 g/L) | peroxide | lauryl ether | | |
| | | | | (20 ml/L) | (0.05 g/L) | | |
| Example | A-11 | BTA | Diglycolic acid | Ammonium | LTM additive | 6.5 | 5 |
| 15 | (100 g/L; 200 nm) | (1 g/L) | (15 g/L) | persulfate | (1 g/L) | | |
| | | | | (15 g/L) | | | |

TABLE 4

| | Polishing particulate | | Compound having carboxyl | Oxidizing | Other | | Ru polishing |
|---|---|---|---|---|---|---|---|
| | (content; particle | Corrosion inhibiting | group in the molecule | agent | component | | rate |
| | diameter) | agent (content) | (content) | (content) | (content) | pH | (nm/min) |
| Example | A-6 | BTA | Citric acid | Hydrogen | — | 8.0 | 9 |
| 16 | (100 g/L; 100 nm) | (1 g/L) | (15 g/L) | peroxide | | | |
| | | | | (20 ml/L) | | | |
| Example | A-12 | BTA | Tartaric acid | Hydrogen | — | 8.5 | 13 |
| 17 | (100 g/L; 60 nm) | (1 g/L) | (15 g/L) | peroxide | | | |
| | | | | (20 ml/L) | | | |
| Example | A-2 | BTA | Methoxyacetic acid | Hydrogen | DBSA | 5.0 | 10 |
| 18 | (100 g/L; 50 nm) | (1 g/L) | (15 g/L) | peroxide | (0.03 g/L) | | |
| | | | | (20 ml/L) | | | |
| Example | A-3 | BTA | Malic acid | Hydrogen | — | 6.5 | 8 |
| 19 | (100 g/L; 300 nm) | (1 g/L) | (15 g/L) | peroxide | | | |
| | | | | (20 ml/L) | | | |

TABLE 5

| | Polishing particulate | | Compound having carboxyl | Oxidizing | Other | | Ru polishing |
|---|---|---|---|---|---|---|---|
| | (content; particle | Corrosion inhibiting | group in the molecule | agent | component | | rate |
| | diameter) | agent (content) | (content) | (content) | (content) | pH | (nm/min) |
| Example | A-13 | BTA | Methoxyacetic acid | Hydrogen | Polyacrylic | 8.5 | 9 |
| 20 | (100 g/L; 50 nm) | (1 g/L) | (15 g/L) | peroxide | acid | | |
| | | | | (20 ml/L) | (1 g/L) | | |
| Example | A-2 | BTA | Glycolic acid | Hydrogen | — | 6.0 | 11 |
| 21 | (100 g/L; 80 nm) | (1 g/L) | (15 g/L) | peroxide | | | |
| | | | | (20 ml/L) | | | |
| Example | A-10 | DBTA | Citric acid | Ammonium | — | 5.0 | 12 |
| 22 | (100 g/L; 200 nm) | (1 g/L) | (15 g/L) | persulfate | | | |
| | | | | (15 g/L) | | | |
| Example | A-14 | BTA | 2-Tetrahydrofurancarboxylic | Ammonium | — | 6.5 | 15 |
| 23 | (100 g/L; 20 nm) | (1 g/L) | acid | persulfate | | | |
| | | | (15 g/L) | (15 g/L) | | | |

TABLE 6

| | Polishing particulate | | Compound having carboxyl | Oxidizing | Other | | Ru polishing |
|---|---|---|---|---|---|---|---|
| | (content; particle | Corrosion inhibiting | group in the molecule | agent | component | | rate |
| | diameter) | agent (content) | (content) | (content) | (content) | pH | (nm/min) |
| Example 24 | A-10 | BTA | Citric acid | Hydrogen | TMA additive | 3.5 | 10 |
| | (100 g/L; 150 nm) | (1 g/L) | (15 g/L) | peroxide | (1 g/L) | | |
| | | | | (20 ml/L) | | | |
| Example 25 | A-12 | BTA | Diglycolic acid | Hydrogen | DBSA | 4.0 | 10 |
| | (100 g/L; 60 nm) | (1 g/L) | (15 g/L) | peroxide | (0.03 g/L) | | |
| | | | | (20 ml/L) | | | |
| Comparative | None | BTA | Tartaric acid | Hydrogen | — | 3.5 | <0.1 |
| example 1 | | (1 g/L) | (15 g/L) | peroxide | | | |
| | | | | (20 ml/L) | | | |
| Comparative | A-15 | BTA | Tartaric acid | Hydrogen | — | 5.0 | 0.9 |
| example 2 | (100 g/L; 150 nm) | (1 g/L) | (15 g/L) | peroxide | | | |
| | | | | (20 ml/L) | | | |

The Mohs scale of hardness of the abrasive particulates described in the abovementioned Tables 1 to 6 are as indicated in the following Table 7.

The “particle diameter” in Tables 1 to 6 indicates the average primary particle diameter of the polishing particulate. The average primary particle diameter of these particulates is a value obtained by observing the polishing particulate with an SEM (scanning electron microscope) and measuring a minimum constituent particle diameter constituting one particle.

TABLE 7

| | Polishing particulate | Mohs scale of hardness |
|---|---|---|
| A-1 | Diamond | 10 |
| A-2 | α-Alumina | 9 |
| A-3 | Zirconium oxide | 7 to 9 |
| A-4 | γ-Alumina | 8 to 9 |
| A-5 | Fused alumina | 9 |
| A-6 | Chromium oxide | 8 to 9 |
| A-7 | Silicon carbide | 8 to 10 |
| A-8 | Iron oxide | 5 to 7 |
| A-9 | Zinc oxide | 5 to 7 |
| A-10 | Cerium oxide | 5 to 7 |
| A-11 | Silicon nitride | 5 to 7 |
| A-12 | Titanium oxide | 5 to 8 |
| A-13 | Cobalt oxide | 5 to 7 |
| A-14 | Manganese oxide | 5 to 7 |
| A-15 | Organic particulate (polyacrylic acid | <1 |
| | particulate) | |

According to the above Tables 1 to 6, it is seen that, when the polishing liquid of Examples 1 to 25 is employed, high polishing rates are obtained even for an Ru film formed by the ALD system. On the other hand, in Comparative Example 1, which does not contain the specific polishing particulate, and in Comparative Example 2, which contains the polishing particulate having a lower Mohs hardness scale, a sufficient polishing rate of an Ru film of a barrier layer could not be obtained. Considering the above, it is understood that, according to the present invention, even when a ruthenium film formed with the ALD system is used for the barrier metal, a superior barrier CMP polishing rate can be obtained by appropriately selecting the polishing particulate of the polishing liquid.

What is claimed is:

1. A polishing liquid for polishing a ruthenium-containing barrier layer, the polishing liquid being used in chemical mechanical polishing for a semi-conductor device having the ruthenium-containing barrier layer and conductive metal wiring lines on a surface thereof, and the polishing liquid comprising:
an oxidizing agent; and
a polishing particulate having hardness of 5 or higher on the Mohs scale and having a composition in which a main component is other than silicon dioxide.

2. The polishing liquid according to claim 1, wherein the polishing particulate has a composition in which the main component is an atom selected from the group consisting of C, Co, Ni, Fe, Zr, Mg, Y, La, Sn, Ce, Pr, Nd, Al, Ti, Cr, Zn, Si, Mn, Dy, Er, Eu, Gd, Ho, La, Lu, Nd, Sc, Sm, Tb, Tm and Yb.

3. The polishing liquid according to claim 1, wherein the polishing particulate comprises a material selected from the group consisting of diamond, γ-alumina, α-alumina, fused alumina, chromium oxide, zirconium oxide, silicon carbide, iron oxide, zinc oxide, cerium oxide, silicon nitride, titanium oxide, cobalt oxide, and manganese oxide.

4. The polishing liquid according to claim 1, wherein the concentration of the polishing particulate is from 0.1% by mass to 15% by mass with respect to the total amount of the polishing liquid.

5. The polishing liquid according to claim 1, wherein the average primary particle diameter of the polishing particulate is in a range of from 10 nm to 500 nm.

6. The polishing liquid according to claim 1, further comprising a corrosion inhibiting agent and a compound containing a carboxyl group in the molecule.

7. The polishing liquid according to claim 6, wherein the compound containing a carboxyl group in the molecule is represented by the following Formula (A):
R^{A1}—O—R^{A2}—COOH Formula (A)
wherein, in Formula (A), R^{A1} and R^{A2} each individually represent a hydrocarbon group.

8. The polishing liquid according to claim 6, wherein the corrosion inhibiting agent is at least one compound selected from the group consisting of 1,2,3-benzotriazole, 5,6-dimethyl-1,2,3-benzotriazole, 1-(1,2-dicarboxyethyl)benzotriazole, 1-[N,N-bis(hydroxylethyl)aminomethyl]benzotriazole, and 1-(hydroxylmethyl)benzotriazole.

9. The polishing liquid according to claim 1, further comprising a cationic quaternary ammonium salt compound.

10. The polishing liquid according to claim 1, further comprising a surfactant.

11. The polishing liquid according to claim 1, further comprising a hydrophilic polymer.

12. The polishing liquid according to claim 1, wherein a ruthenium film of the ruthenium-containing barrier layer is formed by an atomic layer deposition (ALD) process.

13. A polishing method for chemical mechanical polishing of a semi-conductor device, the method comprising:
contacting a polishing liquid comprising an oxidizing agent and a polishing particulate having hardness of 5 or higher on the Mohs scale and a composition in which a main component is other than silicon dioxide, with a surface of a substrate to be polished, the substrate having a ruthenium-containing barrier layer and conductive metal wiring lines on a surface thereof, and
polishing the surface to be polished such that contact pressure from a polishing pad to the surface to be polished is from 0.69 kPa to 20.68 kPa.
